(19) United States
(12) Patent Application Publication
(10) Pub. No.: US 2007/0160373 A1
(43) Pub. Date: Jul. 12, 2007

(54) Distributed illumination and sensing system

(75) Inventors: David Kalman Biegelsen, Portola Valley, CA (US); Daniel G. Bobrow, Palo Alto, CA (US); James Ell Reich, San Francisco, CA (US); Daniel H. Greene, Sunnyvale, CA (US)

Correspondence Address: MARGER JOHNSON & MCCOLLOM/PARC, 210 MORRISON STREET, SUITE 400, PORTLAND, OR, 97204, US

(73) Assignee: Palo Alto Research Center Incorporated

(21) Appl. No.: 11/317,215

(22) Filed: Dec. 22, 2005

(51) Int. Cl. H04B 10/00; H01L 27/00

(52) U.S. Cl. 398/118; 250/208.1

(57) ABSTRACT

A method and system of distributed illumination and sensing, the system including devices, each device including an emitter to emit at least one of light and sound, a sensor to receive an indirect emission, and a controller to determine the existence and/or relative location of at least one of the other devices in response to the indirect emission.

### BACKGROUND

Lighting and light fixtures are installed throughout society. Homes, businesses, streets, vehicles, etc. all have lights of some sort. Such lighting may obtain power from a continuous supply of power provided to the location. Although it is not currently commonplace, lights may be modulated to transmit signals to be detected by devices that are not lights.

Multiple sensor systems may use battery powered sensors. A battery is an inherently finite power supply. Thus, for battery powered sensors, perpetual maintenance of the batteries is required. Adding a radio frequency communication capability to the sensors further increases the power usage and decreases the useful life of the battery.

### SUMMARY

An embodiment includes a system for distributed illumination and sensing. The system includes devices, each device including an emitter to emit at least one of visible light and sound, a sensor to receive an indirect emission, and a controller to determine the existence of at least one of the other devices in response to the indirect emission.

Another embodiment includes a method including providing a plurality of devices, each device including an emitter to emit visible light and/or sound, a sensor, and a controller. Then emitting a signal from a first one of the devices, sensing the signal as an indirect emission in a second one of the devices, the signal only sensed after the signal scatters off of a surface, and determining the existence and/or relative location of the first device in response to the sensed signal.

### BRIEF DESCRIPTION OF THE DRAWINGS

FIG. 1 shows an embodiment of a distributed illumination and sensing system;

FIG. 2 shows a surface scattering an emission from and emitter;

FIG. 3 shows communications links between devices;

FIG. 4 shows a communication link between two networks using an embodiment of a distributed illumination and sensing system;

FIG. 5 shows the relationship of an indirect emission and a sensing volume; and

FIG. 6 shows a flowchart of a method using an embodiment of a distributed illumination and sensing system.

### DETAILED DESCRIPTION

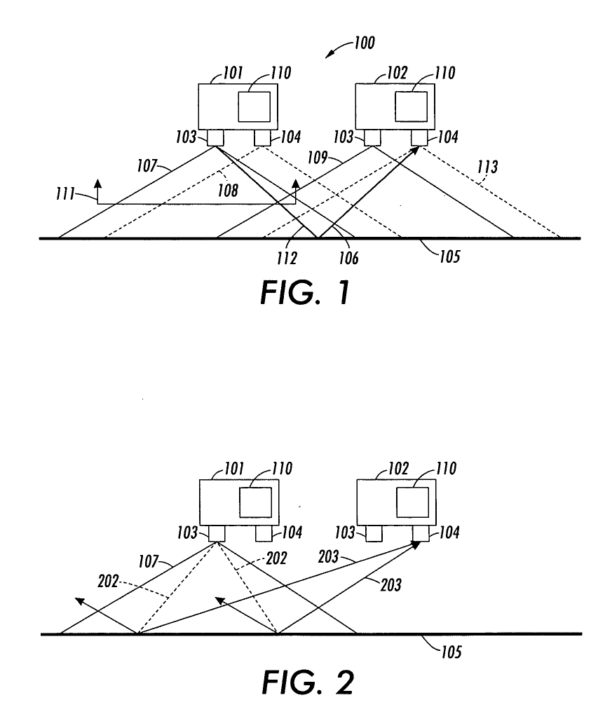

FIG. 1 shows an embodiment of a distributed illumination and sensing system 100. The system 100 includes devices 101 and 102. Each device 101 or 102 includes an emitter 103, a sensor 104, and a controller 110. Although shown as separate units, the emitter 103 and the sensor 104 may be part of the same unit.

The emitter 103 may emit visible light or sound. For example, the emitter 103 may be a light emitting diode (LED), LED array, a fluorescent light, a laser, or any other modulatable source. The light emitted by the emitter 103 does not have to be visible. For example, the emitter 103 may be an infrared emitting LED, emitting light with a wavelength longer than light in the visible spectrum. Alternatively, the emitter may be a fluorescent light or LED emitting ultraviolet light with a wavelength shorter than light in the visible spectrum.

Emission volume 107 shows an example of a volume through which the emitter 103 of device 101 may emit. An emission volume 107 is defined as the volume through which an emission may pass before reflecting or scattering. The emission volume 107 is not limited to one particular volume. For example, a laser may emit a collimated beam of light occupying a narrow volume. A fluorescent light or a laser dispersed by an optical element may emit light through a larger volume. Furthermore, the emission is not limited to filling the entire volume. For example, the light may be emitted such that the light passing through a plane 111 intersecting the emission volume 107 may project a circle on the plane 111. Thus, no light would pass through the center of the plane 111 intersecting the emission volume 107, but light would pass through the edges of the intersection.

In addition, the emission volume 107 and the flux density of light passing through the emission volume 107 may not be fixed in time. For example, an emitter 103 may track an object passing the device 101. The emission volume of the emitter 103 may move to continually encompass the object. For example, the device 101 may be a spotlight tracking an actor on a stage. The projection of the light may be in a changing shape. For example, initially, an emitter 103 may emit a cone of light, projecting a circle through plane 111. Then the emitter 103 may change, emitting light through a grid pattern of the plane 111.

Although emissions have been described as passing through a plane 111, the plane 111 need not exist. The plane 111 was used to illustrate the flux density of the emissions from the emitter 103.

Furthermore, although the emission from an emitter 103 has been described as light, such emission may be any signal that is part of the electromagnetic or acoustic spectrum. For example, the emitter 103 may be an antenna emitting electromagnetic signals in the range of 2 to 3 GHz.

Similar to the emission of the light as described above, the emitter 103 may emit sound. For example, the sound may be an ultrasonic beam. Similar to the light described above, the sound may be limited to an emission volume 107, may have different flux densities through a plane 111, may occupy different wavelengths, and may change over time.

Although such emissions have been described as having a wavelength, such emissions may occupy a range of wavelengths with varying intensities. For example, a fluorescent light may emit both visible and ultraviolet light, and an LED array may emit both visible and infrared light. An acoustical emitter may emit sound in both audible and ultrasonic wavelengths.

Although particular emitters emitting signals in particular media have been described, such emitters may emit any signal that is capable of reflecting or scattering off of a surface to some degree. Such signals may be detectable by humans, such as visible light and audible sound, and such signals may be undetectable by humans without a measuring device, such as RF signals, infrared light, and ultrasound.

Similar to the wide variety of possible emitters 103, there is a wide variety of possible sensors 104. The sensor 104 may be capable of sensing any of the above described emissions. For example, the sensor 104 may be a photosensor to sense light, a microphone to sense sound, or an antenna to sense RF signals. Furthermore, the sensor 104 may be a combination of multiple types and multiple instances of one type. For example, a sensor 104 may be an array of photosensors. A particular example may be a digital camera. The sensor 104 may also be an array of microphones or other sound sensing units. In addition, the sensor 104 may be an array of antennae for sensing RF signals and a microphone for sensing sound.

The sensor 104 may receive an indirect emission 106. As shown in FIG. 1, an emitter 103 of a device 101 emits, as part of its emission, a directed emission 112. After reflecting or scattering off of a surface 105, the directed emission 112 becomes an indirect emission 106. Thus, indirect emission 106 is any emission that, after being emitted from an emitter 103, reflects, scatters, or otherwise deviates from its original path at a surface 105.

The controller 110 determines the existence of other devices in response to the indirect emission 106. A device 101 may modulate the signal emitted from its emitter 103 with information. The information may include an identification of the device 101. This emission then may reflect or scatter from the surface 105 and be received in the sensor 104 of the device 102. The controller 110 of the device 102 may extract the identification from the signal received by the sensor 104. Since the identification of the device 101 was encoded in the indirect emission 106, the controller 110 may determine that the device 101 exists because it received an indirect emission from that device.

Although, as described above, an emitter 103 may emit a direct emission 112 that becomes an indirect emission 106, the path of a signal from an emitter 103 to a sensor 104 may take a path different from the illustrated path. FIG. 2 shows a surface scattering an emission from and emitter. If the emission from the emitter 103 intersects a surface 105 that scatters the emission, an indirect emission 203 may emanate from the surface 105 at an angle different from the angle of the direct emission 202 relative to the surface 105. Furthermore, the angle of any indirect emissions from the surface 105 need not all be at the same angle.

As shown in FIG. 2, direct emissions 202 scatter from the surface 105, producing, among others, indirect emissions 203 directed towards the sensor 104 of device 102. Hence, because of the scattering, any path of a direct emission 202 from the emitter 103 may result in an indirect emission 203 directed towards the sensor 104 of the device 102. In other words, the sensor 104 of device 102 may sense the projection of the direct emissions 202 from the emitter 103 of device 101 as scattered from the surface 105.

The controller 110 of the device 102 may determine the relative position of the device 101 from the projection. For example, if the projection on the surface 105 forms a particular shape, the sensor 104 of the device 102, in this case an imaging sensor such as a camera, may sense the projection as distorted because of relative position of the device 102. By comparing the received projection with an expected projection, the controller 110 may determine the relative position of the other device. By associating the identification of that device received from the indirect emission, the device 102 has determined the relative position of a particular known device.

Although determining the existence of one device and determining the relative position of that device relative to a device sensing an indirect emission has been described, one device may determine the existence and relative position of multiple devices in response to multiple indirect emissions.

A device 101 may include an absolute position measurement. Absolute position measurement as used herein is a measurement of a position of the device 101 relative to any object that is not a device of the system 100. For example, for a device 101 installed in the front door of a house, a position of the device 101 relative to the front door would be an absolute position measurement. In another example, for a device 101 installed in a vehicle, a position of the device 101 relative to the driver's seat of the vehicle is an absolute position measurement even though the vehicle may be mobile.

Furthermore, the absolute position measurement for a device 101 need not be fixed for an installed device. For example, a device 101 may be installed in a crane in a warehouse that is mobile relative to the warehouse entrance. The absolute position measurement may be in reference to the warehouse entrance. The absolute position measurement of the device 101 may be modified as the crane moves to maintain that measurement as an absolute position measurement relative to the warehouse entrance.

A device 101 may communicate the absolute position measurement to another device 102. Since the device 102 may determine its position relative to the device 101 with the absolute position measurement, the device 102 may determine its absolute position measurement by combining the absolute position measurement from the device 101 and its position relative to the device 101. Thus, for a system 100, devices may determine their absolute position measurement if one of the devices has an absolute position measurement.

The devices 101 and 102 may form a communications link between them. As described above, a device 102 may receive an indirect emission from a device 101. By encoding information as amplitude-, frequency-, or other modulation of the directed emission and thereby of the indirect emission, device 101 may send information to device 102. Similarly, device 102 may send information to device 101 using an indirect emission from device 102 sensed in device 101. Thus a two way communications link may be established over the indirect emissions between a pair of devices.

The communications link is not limited to one pair of devices in a system 100. Any number of pairs of devices may form communications links between each other. Furthermore, any one device may belong to multiple pairs of devices forming communications links.

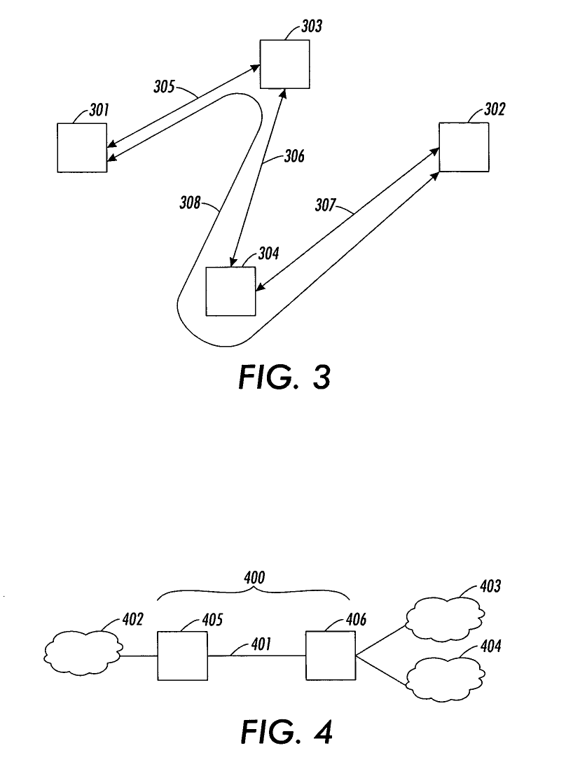

In addition, two devices may not be able to receive indirect emissions from each other. Thus, a direct communications link between the two may not operate. However, a communications link between the two devices may be established through other devices capable of forming communications links with those devices. FIG. 3 shows communications links between devices. Devices 301 and 303 are coupled by a communications link 305. Devices 303 and 304 are coupled by a communications link 306. Devices 302 and 304 are coupled by a communications link 307. Devices 301 and 302 are not coupled by a direct communications link. However, communications from device 301 bound for device 302 may be sent to device 303 over communications link 305, then to device 304 over communications link 306, then to device 302 over communications link 307. Similarly, communications from device 302 may follow a reverse path through the intervening devices and links. Thus, a communication link 308 between device 301 and 302 may be formed using the intervening devices, even though device 301 and 302 may not be capable of receiving indirect emissions from each other.

In addition to the communications links described above, devices may also communicate over their power lines or over other non-local media such as RF or wired Ethernet. Such communication media behave as common communication buses. Thus, being a bus, no locational information can be derived, and all communication bandwidth must be shared among all devices on the bus. In contrast, communications using indirect emissions allow for local communication and relative location determination.

As described above, a device 301 may transmit an absolute position measurement to another device 303. If a device 302 does not receive indirect emissions from a device 301 having an absolute position measurement, a communication from a device 301 having an absolute position measurement may be forwarded to the device 302 not receiving those indirect emissions. Alternatively, devices 303 and 304 intervening between a device 301 having an absolute position measurement and another device 302 may receive the absolute position measurement, modify it using the receiving device's relative position to the transmitting device, and transmit that modified measurement as an absolute position measurement. Thus, device 302 could derive an absolute position determination even though no device that it has direct communications with has an actual absolute position measurement.

FIG. 4 shows a communication link between two networks using an embodiment of a distributed illumination and sensing system 400. Device 405 and device 406 are linked by their indirect emissions forming a communications link 401. Device 405 is coupled to a first network 402. Device 406 is coupled to a second network 403. Each device coupled to a network may communicate with the network. If a communications link between the two networks is desired, the link may be formed through the devices 405 and 406 and the associated communications link 401. Thus, the system 100 may bridge communications between two networks.

Although two devices, 405 and 406, have been shown in reference to bridging two networks 402 and 403, a system 400 having multiple devices may be used to bridge the networks. For example, as described above, a communications link may be formed between two devices using other devices of the system. Thus, communications between the two networks attached to the two devices may pass through the other devices in the network.

In addition, although two networks, 402 and 403, coupled to the system 400 have been described, any number of networks may be coupled to the system 400. For example, one device may be coupled to multiple networks such as device 406 and networks 403 and 404. Alternatively, the system may be coupled to more than two networks with each network coupled to an associated device.

Referring to FIG. 1, a device 101 of a system 100 may include an emitter that emits visible light. Thus, the device 101 may be installed where a light normally would be installed. For example, a device 101 may be installed in overhead lighting illuminating a room or hallway. Any fixture that is capable of holding a light may be replaced or augmented with a device 101.

A system may include a master device and slave devices. The master device may control some or all of the operations of the slave devices. The control may be implemented through communications links established through the devices. As described above, the communications link between a master device and a slave device need not be a direct connection. The connection may pass through other devices of the system, including devices that are neither slave devices nor master devices.

The slave devices may provide illumination with their emitters. The master device may control the illumination provided by the slave devices. For example, a master device may receive a turn-on signal. In response, the master device may turn its emitter on, illuminating an area, and send commands to the slave devices, commanding them to turn their emitters on, illuminating the same or other areas. Furthermore, the master device may control each slave device individually. For example, the combination of a master device and associated slave devices may be capable of multiple illumination patterns. The master device may receive a signal for a particular illumination pattern. The master device would selectively turn the slave devices emitters on and off, or modify the output of the emitters to achieve the desired illumination pattern.

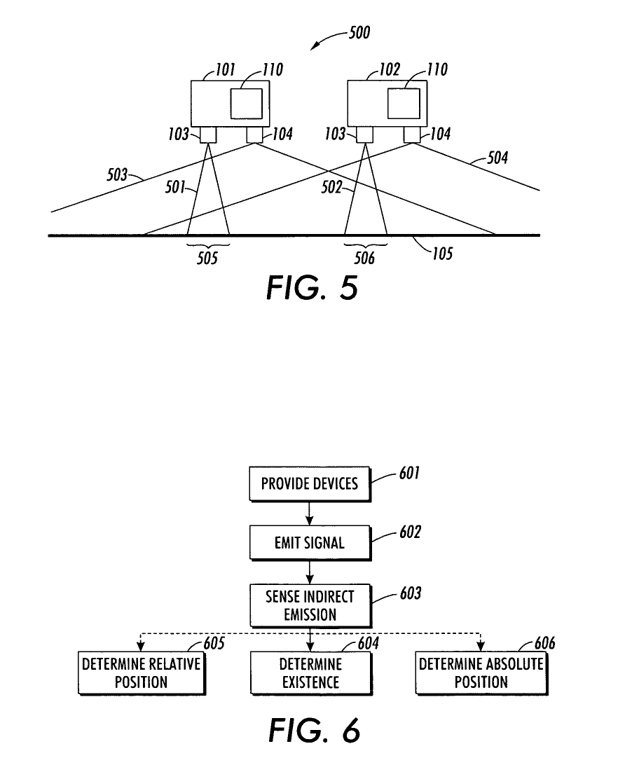

FIG. 5 shows the relationship of an indirect emission and a sensing volume. The emission volume 501 through which an emitter may emit need not be the same as the sensing volume. Furthermore, the emission volumes of two devices may, but need not overlap. The system 500 has two devices, 101 and 102. Both devices 101 and 102 emit light on a surface 105. Projection areas 505 and 506 show where the light reflects or scatters from the surface 105. The emission volumes 501 and 502 of the devices 101 and 102 do not overlap. Each device 101 and 102 has a sensing volume 503 and 504. The sensing volume of each device overlaps the projection area of the other device. Thus, each device may sense the indirect emission of the other even though the emissions of the devices do not overlap.

FIG. 6 shows a flowchart of a method using a distributed illumination and sensing system. Devices forming the system are provided in 601. A first device emits a signal in 602. That signal is sensed by a second device in 603 as an indirect emission. In other words, the signal is sensed after it reflects or scatters from a surface. From the indirect emission, the existence of the device sending the indirect emission is determined by the device sensing the indirect emission in 604.

The second device may determine the relative position of the first device. From the spatial pattern of the indirect emission, the second device determines its position relative to the first device in 605. Similarly the first device may determine its relative position to the second device. These relative positions may be communicated between the devices, thereby improving each one's determination. The process can be assisted by the first device modulating its illumination pattern or volume, communicating the state of its emitter. By communicating its state, for example, the conical angle of directed emission, the second device can more easily and accurately determine the relative location of the first device. Furthermore, the modulation scheme can be used to distinguish overlapping indirect emissions coming from neighboring devices.

In addition, one of the devices may contain an absolute position measurement. By sending the absolute position measurement to other devices, the other devices may determine their absolute position using the received absolute position measurement and the relative position of the device sending the absolute position measurement as in 606.

As described above, the devices of the system may form a communications link between each other. The communications link between two devices may be formed using the indirect emissions from each device. To form a communications link, a device may modulate the emissions from its emitter. For example, if the emitter is an LED, the device may modulate the intensity of the light from the LED. In addition, the device may vary the frequency of the emission. For example, an acoustical emitter may vary the frequency of the emitted sound. Although two types of modulation have been described for two different emitters, both types and other types may be used when modulating any emitter. Furthermore, direct modulation is not required. For example, an external modulator may modulate an LED emitting a fixed intensity light. In addition, the modulations generally occur far faster than can be perceived by a human observer. However, in certain applications the modulation from one or more devices can be intentionally noticeable by human observers.

A second device may sense an indirect emission from a first device that is modulating the indirect emission. The modulated indirect emission may be demodulated to extract the content modulated on the indirect emission. This content may be a communication from the first device to the second device. Thus, a communications link is formed from the first device and the second device. Furthermore, a similar communications link may be formed from the second device to the first device using the emitter of the second device and the sensor of the first device. Thus, a two way communications link may be formed between two devices.

In addition, an emitter and sensor pair facilitating the communications in one direction may be different from the emitter and sensor pair facilitating communications in the other direction. Thus, the types of emitters and sensors and the medium used by the emitters and sensors may be different in the two directions.

Furthermore, a device is not limited to communicating with one other device. A device may form communications links with any number of other devices capable of sensing its indirect or direct emissions. However, unlike a shared communications bus, other devices beyond the range of the indirect and direct emissions are immune from interference from this device, and may use their full complement of bandwidth without regard for data sent over this channel

As described above, a first device of a system may be coupled to a first network and a second device of the system may be coupled to a second network. The first device may receive data from the first network. The first device may send the data from the first network to the second device. The second device, coupled to the second network, may send data to the second network. The data sent to the second network may include data received from the first device, including the data received from the first network. Thus, data from the first network may be transmitted to the second network. Similarly, data from the second network may be transmitted to the first network through the first and second devices. Thus, communications between the first and second networks may be established using the first and second devices.

As described above, a communications link for a variety of purposes may be established between devices using indirect emissions. However, communications links between devices may be established using other means. For example, devices may be installed in light fixtures in a room, receiving power from a common power supply. By modulating signals on the power lines supplying power to the devices, each device may communicate with other devices coupled to the same power supply. In addition, the devices may communicate via other long-range methods, such as RF or wired Ethernet. Although such communications links may be established, devices would still use received indirect emissions to determine the existence and positioning of other devices.

The devices forming the system may change over time. Devices may be added or removed from the system. For example, consider an existing system formed of devices installed illuminating an area. An additional device may be added to increase the area of illumination. The additional device may begin receiving indirect emissions from the other devices and emitting its own indirect emissions. Thus the additional device becomes a part of the system. Alternatively, if an illumination requirement of an area changes removing the need for a particular device, that device may be removed from the system.

Furthermore, separate systems may be merged to form one system. For example, consider two systems installed in separate areas. As installed, the devices of one system do not receive indirect emissions from devices of the other system. If a new device is added that may receive indirect emissions from both original systems, a new system is formed including the devices of the original systems and the new device. Although forming a new system has been described using a new device, a new device is not required. For example, if a limitation preventing devices of a system from receiving indirect emissions from the other system is removed, the two systems may merge into a single system.

The formation of a new system may be transitory. For example, one system may be installed in a home. A second system may be installed in a vehicle. When the devices of the system in the vehicle may receive indirect emissions from the devices of the system in the house, e.g. when the vehicle is in a garage, the devices of the house system and the vehicle system may form one system. When the vehicle moves out of range of the indirect emissions of the system of the house, the system may divide into the two separate vehicle and house systems.

Although forming a new system out of two original systems has been described, such a new system is not required. The two original systems may remain distinct. Regardless of the formation of a new system, the devices of the two systems may still communicate with each other.

It will be appreciated that various of the above-disclosed and other features and functions, or alternatives thereof, may be desirably combined into many other different systems or applications. Also that various presently unforeseen or unanticipated alternatives, modifications, variations, or improvements therein may be subsequently made by those skilled in the art which are also intended to be encompassed by the following claims.

1. A system comprising:
a plurality of devices, each device including:
an emitter to emit at least one of the group consisting of electromagnetic radiation and acoustic radiation;
a sensor to receive an indirect emission; and
a controller to determine the existence of at least one of the other devices in response to the indirect emission.

2. The system of claim 1, the emitter of at least one of the devices further comprising at least one selected from the group consisting of an infrared emitter, an ultraviolet emitter, a visible light emitter, an acoustical emitter, a directional RF signal emitter, a human detectable signal emitter, and a human undetectable signal emitter.

3. The system of claim 1, the sensor of at least one of the devices further comprising at least one selected from the group consisting of a photosensor, a camera, a microphone, and an antenna.

4. The system of claim 1, further comprising at least one selected from the group consisting of:
the controller of each device further to determine a relative position of the device relative to at least one of the other devices in response to the indirect emission received by the sensor of that device; and
the controller of each device further to determine the relative position of the device relative to at least one of the other devices in response to an emission source and state encoded in the indirect emission and any sensed distortion, scaling and position of a shape of the indirect emission received by the sensor of that device.

5. The system of claim 4, wherein:
at least one of the devices further comprises an absolute position measurement; and
each device further to determine an absolute position of the device in response to the absolute position measurement.

6. The system of claim 1, further comprising:
a pair of the devices, each of the devices of the pair further to receive an indirect emission from the other device; and
a communications link to enable communications through the pair using the indirect emissions of the pair.

7. The system of claim 1, further comprising:
a first network, a first one of the devices to communicate with the first network;
a second network, a second one of the devices to communicate with the second network; and
a communications link between the first and second device to enable communications between the first and second networks.

8. The system of claim 1, further comprising:
a master device selected from the plurality of devices; and
a plurality of slave devices selected from the plurality of devices, the slave devices to be controlled by the master device.

9. The system of claim 1, wherein at least one of the devices is installed in a light fixture.

10. The system of claim 1, further comprising, for each device receiving an indirect emission, a sensing volume of one of the at least one sensors of the device, the sensing volume intersecting with a projection of the indirect emission on a surface.

11. A method comprising:
providing a plurality of devices, each device including:
an emitter to emit at least one of the group consisting of visible light and sound, a sensor, and
a controller;
emitting a signal from a first one of the devices;
sensing the signal as an indirect emission in a second one of the devices, the signal only sensed after the signal scatters off of a surface; and
determining the existence of the first device in response to the sensed signal.

12. The method of claim 11, further comprising one selected from the group consisting of:
determining the relative position of the first and second devices in response to the indirect emission; and
determining the relative position of the first and second devices in response to at least one selected from the group consisting of a distortion, a position, and a scale of the received indirect emission.

13. The method of claim 11, further comprising determining the absolute position of the first and the second devices in response to at least one selected from the group consisting of a distortion, a position, and a scale of the received indirect emission.

14. The method of claim 11, further comprising one selected from the group consisting of:
communicating between the first and second devices using the indirect emission; and
communicating between the first and second devices using the indirect emission and at least one selected from the group consisting of wired Ethernet, wireless Ethernet, and a power line common to the first and second devices.

15. The method of claim 14, further comprising:
communicating between the first device and a first network;
communicating between the second device and a second network; and
communicating between the first network and the second network through the first and second devices.

16. The method of claim 14, communicating between the first and second devices further comprising modulating the signal from the first device.

17. The method of claim 11, further comprising controlling the second device using the first device.

18. The method of claim 11, further comprising illuminating an area using emitters of at least one of the plurality of devices.

19. The method of claim 11, providing the plurality of devices further comprising installing at least one of the devices in a light fixture.

20. The method of claim 11, further comprising:
emitting the signal directed at a surface; and
sensing the indirect emission of the projection of the indirect emission on the surface intersects with a sensing volume of the sensors of the second device.
